(19) United States
(12) Patent Application Publication
(10) Pub. No.: US 2015/0136451 A1
(43) Pub. Date: May 21, 2015

(54) ELECTRONIC COMPONENT MODULE

(71) Applicant: SAMSUNG ELECTRO-MECHANICS CO., LTD., Suwon-Si (KR)

(72) Inventors: Heung Woo PARK, Suwon-Si (KR); Do Jae YOO, Suwon-Si (KR); Tae Hyun KIM, Suwon-Si (KR)

(73) Assignee: SAMSUNG ELECTRO-MECHANICS CO., LTD., Suwon-Si (KR)

(21) Appl. No.: 14/268,970

(22) Filed: May 2, 2014

(30) Foreign Application Priority Data
Nov. 20, 2013 (KR) 10-2013-0141682

(51) Int. Cl. H05K 1/18; H05K 13/04

(52) U.S. Cl. CPC H05K 1/181; H05K 13/046
USPC 174/255; 29/841

(57) ABSTRACT

There is provided an electronic component module including: a substrate on which an electronic component is mounted; at least one insulating member coupled to the substrate and having a surface on which a plating layer is formed; and a molded portion covering the electronic component and the at least one insulating member, wherein the insulating member is bonded to the substrate and a metal layer is formed on a bonding surface between the substrate and the insulating member.

### CROSS-REFERENCE TO RELATED APPLICATION

This application claims the benefit of Korean Patent Application No. 10-2013-0141682 filed on Nov. 20, 2013, with the Korean Intellectual Property Office, the disclosure of which is incorporated herein by reference.

### BACKGROUND

The present disclosure relates to an electronic component module.

As demand for mobile electronic devices has rapidly increased recently, compact lightweight electronic component modules used in mobile electronic devices are in continuous demand.

However, due to an increase in overall functionality of mobile electronic devices and an increase in precision thereof, amounts of signals to be connected in an electronic component module are continuously increasing.

Accordingly, in an electronic component module, a large number of electronic components may be densely mounted, and a circuit line, via which the respective electronic components are connected, may be provided, while multiple electronic components may be connected to a substrate. That is, the integration of an electronic component module and high densification thereof are required.

Examples of methods of connecting the electronic components and the substrate in manufacturing the electronic component module as described above include a soldering method and a method using a laser via formation method.

In the soldering method, the electronic components and the substrate are connected to one another by using a solder. However, it may be difficult to reduce a distance between the electronic components or a distance between conductors included in the electronic component module.

Also, in the laser via formation method, it may be difficult to perform accurate processing, due to a reduction in size of electrodes, resulting from miniaturization of the electronic components.

### SUMMARY

An aspect of the present disclosure may provide an electronic component module capable of being miniaturized and thin by achieving a fine pitch between signal connection terminals.

An aspect of the present disclosure may also provide an electronic component module having an increased reliability through improvements in adhesive force between a signal connection terminal and a molded portion.

An aspect of the present disclosure may also provide an electronic component module manufactured with a simplified process and reduced costs.

According to an aspect of the present disclosure, an electronic component module may include: a substrate on which an electronic component is mounted; at least one insulating member coupled to the substrate and having a surface on which a plating layer is formed; and a molded portion covering the electronic component and the at least one insulating member, wherein the insulating member is bonded to the substrate and a metal layer is formed on a bonding surface between the substrate and the insulating member.

An upper surface of the insulating member may be exposed to the outside of the molded portion, and a metal layer may be formed on an upper surface of the insulating member.

The metal layer may be an under bump metallurgy layer.

The plating layer may be connected to the metal layer.

An upper surface of the molded portion and the upper surface of the insulating member may be disposed on the same plane.

A plurality of insulating members may be provided, and a distance between adjacent insulating members among the plurality of insulating members may be less than a length of each of the insulating members.

The molded portion may be formed of one of a silicone gel, an epoxy molding compound (EMC), and polyimide.

The insulating member may be vertically coupled to the substrate.

According to another aspect of the present disclosure, an electronic component module may include: a substrate on which an electronic component is mounted; at least one conductive member vertically coupled to the substrate; and a molded portion covering the electronic component and the at least one conductive member, wherein an upper surface of the conductive member is exposed to the outside of the molded portion.

The upper surface of the conductive member and an upper surface of the molded portion may be disposed on the same plane.

A plurality of conductive members may be provided, and a distance between adjacent conductive members among the plurality of conductive members may be less than a length of each of the conductive members.

According to another aspect of the present disclosure, a method of manufacturing an electronic component module may include: forming a metal layer on each of upper and lower surfaces of at least one insulating member; providing a dummy member on which a photoresist layer is formed; bonding the upper surface of the insulating member to a surface of the dummy member; removing a remaining portion of the insulating member except a portion thereof corresponding to the metal layer; forming a plating layer on a surface of the insulating member; bonding a substrate, on which an electronic component is mounted, to the insulating member; forming a molded portion to cover the electronic component and the insulating member; and removing the dummy member.

The removing of the dummy member may include removing both the photoresist layer and the dummy member such that the metal layer formed on the upper surface of the insulating member is exposed to the outside of the molded portion.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view illustrating an electronic component module according to an exemplary embodiment of the present disclosure; and

FIGS. 2 through 8 are conceptual diagrams illustrating a method of manufacturing an electronic component module according to an exemplary embodiment of the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

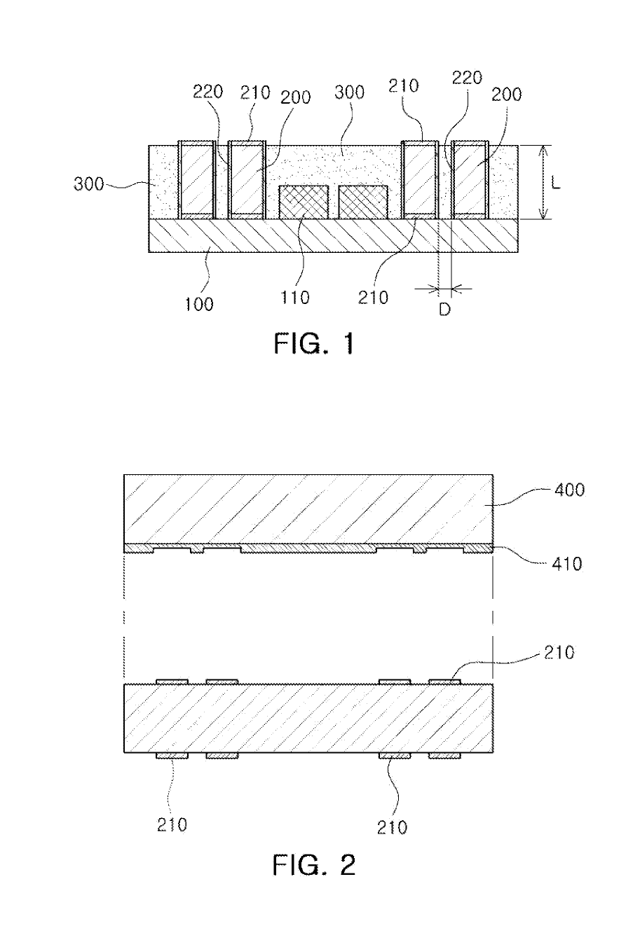

FIG. 1 is a schematic cross-sectional view illustrating an electronic component module according to an exemplary embodiment of the present disclosure.

Referring to FIG. 1, the electronic component module may include a substrate 100, an electronic component 110, at least one insulating member 200, and a molded portion 300.

An electrical signal is transmitted between the electronic components 110 through the substrate 100, and the substrate 100 may be, for example, a rigid substrate, a flexible substrate, a low temperature co-fired ceramics (LTCC) substrate, a multilayer substrate, or a semiconductor-mounting substrate (e.g., a ball grid array (BGA), a fine-pitch BGA (FBGA), or a tape BGA (TBGA)).

The electronic component 110 may include various electronic elements such as a passive element and an active element, and any electronic elements able to be mounted on the substrate 100 may be used as the electronic component 110.

That is, the electronic component 110 according to the exemplary embodiment of the present disclosure may include an active element such as a semiconductor chip and various passive elements.

The electronic component 110 may be mounted on the substrate 100, and at least one insulating member 200 may be disposed around the electronic component 110 as a signal connection terminal.

Here, in order for the insulating member 200 to function as a signal connection terminal, a plating layer 220 may be formed on a surface of the insulating member 200.

The insulating member 200 may be vertically coupled to the substrate 100, and a metal layer 210 may be formed on a bonding surface between the insulating member 200 and the substrate 100.

The molded portion 300 may be provided between the electronic component 110 mounted on the substrate 100 and the insulating member 200 so as to prevent short circuits between the electronic component 110 and the insulating member 200 including the plating layer 220. Furthermore, the molded portion 300 may surround the electronic component 110 and the at least one insulating member 200 to fix the same, thereby safely protecting the electronic component 110 and the at least one insulating member 200 from external impacts.

In detail, the molded portion 300 may cover the electronic component 110 and the at least one insulating member 200.

The molded portion 300 may be formed to cover and seal the electronic component 110 and the at least one insulating member 200, thereby protecting the electronic component 110 and the at least one insulating member 200 from an external environment.

Also, the molded portion 300 may surround the electronic component 110 and the at least one insulating member 200 to fix the electronic component 110 and the at least one insulating member 200 in place to thereby safely protect the electronic component 110 and the at least one insulating member 200 from external impacts.

Also, the molded portion 300 may support the insulating member 200 to thereby maintain verticality of the insulating member 200 vertically coupled to the substrate 100.

The molded portion 300 may be formed by using a molding method, and in this case, at least one of a silicone gel, an epoxy mold compound (EMC), and polyimide, having high thermal conductivity, may be used as a material of the molded portion 300.

However, the embodiments of the present disclosure are not limited thereto, and other various methods such as a method of compressing a semi-cured resin may also be used to form the molded portion 300, as needed.

Here, an upper surface of the molded portion 300 and an upper surface of the insulating member 200 may be disposed on the same plane. Accordingly, the upper surface of the insulating member 200 may be exposed to the outside of the molded portion 300, and the metal layer 210 may be formed on the upper surface of the insulating member 200 exposed to the outside of the molded portion 300.

That is, the metal layer 210 may be formed on the bonding surface between the insulating member 200 and the substrate 100 (that is, a lower surface of the insulating member 200) and on the upper surface of the insulating member 200, which is opposite to the bonding surface.

The metal layer 210 may be an under bump metallurgy layer, and may be formed on both the upper and lower surfaces of the insulating member 200 to function as a signal connection terminal together with the plating layer 220.

Meanwhile, a plurality of insulating members 200 may be coupled to the substrate 100; in this case, the plurality of insulating members 200 may be disposed to be adjacent to one another.

For example, as the plurality of insulating members 200 may be disposed and integrated on the substrate 100 to be adjacent to one another, distances between adjacent insulating members among the plurality of insulating members 200 may be reduced, and a fine pitch may be achieved accordingly.

Here, a distance D between the insulating members 200 may be less than a length L of each of the insulating members 200.

That is, D<L may be satisfied.

According to the exemplary embodiment of the present disclosure, at least one insulating member 200, the plating layer 220 plated on the surface of the insulating member 200, and the metal layer 210 formed on each of the upper and lower surfaces of the insulating member 200 are provided to function as a signal connection terminal; however, the present inventive concept is not limited thereto, and a conductive member may also be used as a signal connection terminal.

For example, at least one conductive member may be vertically coupled to the substrate 100, and the molded portion 300 may be formed to cover the electronic component 110 and the at least one conductive member.

Here, the upper surface of the molded portion 300 and an upper surface of the at least one conductive member may be disposed on the same plane, and the upper surface of the conductive member may be exposed to the outside of the molded portion 300.

Also, similar to the above-described embodiment in which the insulating member 200, the plating layer 220, and the metal layer 210 are used as the signal connection terminal, a plurality of conductive members may be vertically coupled to the substrate 100 to be adjacent to one another.

Thus, distances between adjacent conductive members among the plurality of conductive members may be reduced, and a fine pitch may be achieved accordingly.

Here, a distance between the conductive members may be less than a length of each of the conductive members.

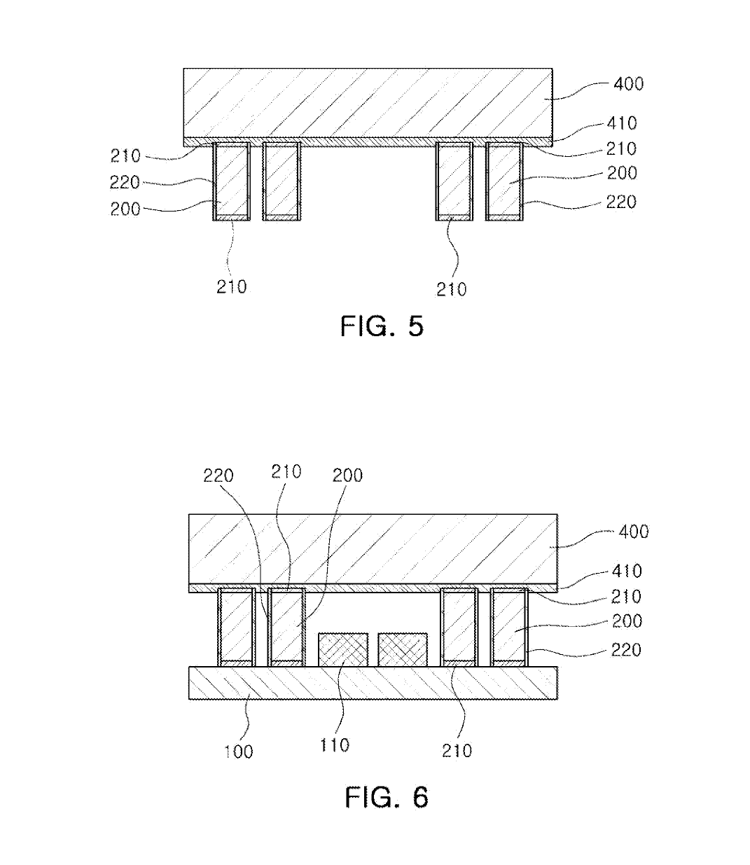

Hereinafter, a method of manufacturing an electronic component module according to an embodiment of the present disclosure will be described with reference to FIGS. 2 through 8.

FIGS. 2 through 8 are conceptual diagrams illustrating a method of manufacturing an electronic component module according to an exemplary embodiment of the present disclosure.

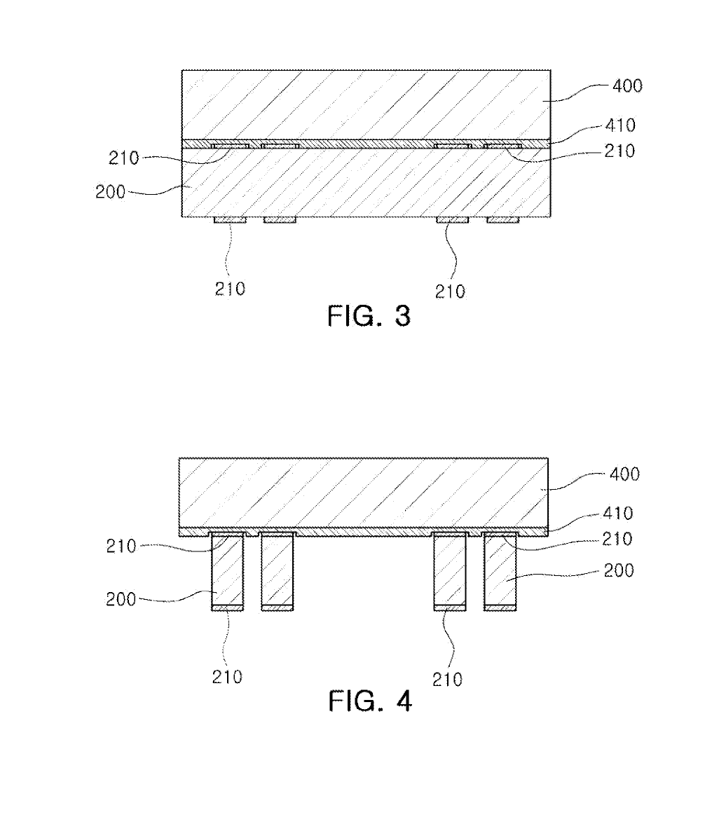

Referring to FIGS. 2 and 3, first, the metal layer 210 is formed on each of the upper and lower surfaces of the insulating member 200. The metal layer 210 may be an under bump metallurgy layer and may be a circuit pattern or a rewiring layer.

The insulating member 200 may be a Si substrate, but is not limited thereto.

Also, one surface of a dummy member 400 having a photoresist layer 410 formed thereon may be bonded to the upper surface of the insulating member 200.

Accordingly, the photoresist layer 410 and the upper surface of the insulating member 200 are bonded to each other.

Also, a groove may be formed in the photoresist layer 410 to accommodate the metal layer 210 formed on the upper surface of the insulating member 200.

A width of the groove may be greater than a width of the metal layer 210.

Referring to FIGS. 4 through 6, a remaining portion of the insulating member 200 other than a portion thereof corresponding to the metal layer 210 may be removed. Here, for example, an etching process may be used.

When the remaining portion of the insulating member 200 except the portion thereof corresponding to the metal layer 210 is removed, the plating layer 220 is formed on a surface of the remaining portion of the insulating member 200.

In this case, the plating layer 220 may be connected to the metal layer 210 formed on each of the upper and lower surfaces of the insulating member 200.

Accordingly, the plating layer 220 may function as a signal connection terminal together with the metal layer 210 formed on each of the upper and lower surfaces of the insulating member 200.

Referring to FIG. 6, a surface of the substrate 100 having the electronic component 110 mounted thereon may be bonded to the insulating member 200.

Here, the insulating member 200 may be vertically coupled to the surface of the substrate 100, and the metal layer 210 may be disposed on a bonding surface between the insulating member 200 and the substrate 100.

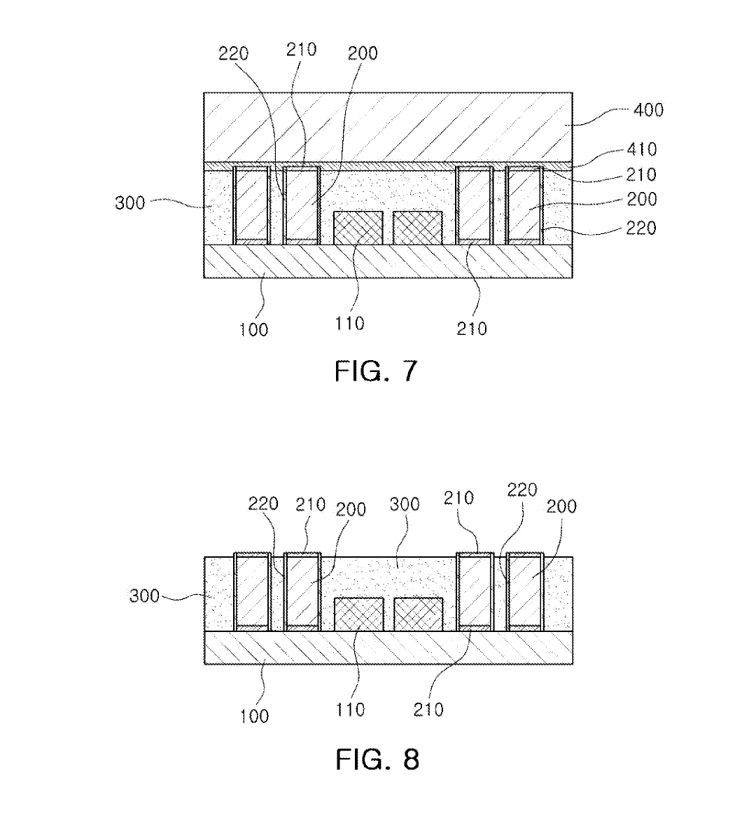

Referring to FIGS. 7 and 8, a molding resin may be injected into space between the dummy member 400 and the substrate 100 to form the molded portion 300 so as to cover the electronic component 110 and the insulating member 200.

The molded portion 300 may be formed by using a molding method, and in this case, at least one of a silicone gel, an EMC, and polyimide, which have high thermal conductivity, may be used as a material of the molded portion 300.

After the molded portion 300 is formed, the dummy member 400 may be removed.

As the photoresist layer 410 is also removed, the metal layer 210 formed on the upper surface of the insulating member 200 may be exposed to the outside of the molded portion 300.

In the electronic component module according to the exemplary embodiment of the present disclosure, a signal connection terminal may be formed on the substrate 100 before forming the molded portion 300.

Also, as the signal connection terminal may be vertically disposed with respect to the surface of the substrate 100 and a plurality of signal connection terminals may be adjusted to be disposed adjacently to one another in an arrangement process, a fine pitch may be achieved.

Also, as the signal connection terminal is formed on the substrate 100 and the molded portion 300 is formed thereafter, adhesive force between the signal connection terminal and the molded portion 300 may be increased.

Accordingly, the molded portion 300 may firmly support the signal connection terminal, and thus, reliability of the electronic component module with respect to external impacts or the like may be provided.

In addition, as the metal layer 210, which may be used as the circuit pattern or the rewiring layer, is formed in advance and then the molded portion 300 is formed, a process of forming a circuit pattern or a rewiring layer is not additionally required.

As set forth above, according to exemplary embodiments of the present disclosure, a fine pitch may be achieved between signal connection terminals, and thus an electronic component module may be miniaturized and slim.

In addition, reliability of the electronic component module may be improved by increasing adhesive force between signal connection terminals and a molded portion.

Also, a manufacturing process may be simplified and manufacturing costs may be reduced.

While exemplary embodiments have been shown and described above, it will be apparent to those skilled in the art that modifications and variations could be made without departing from the spirit and scope of the present disclosure as defined by the appended claims.

What is claimed is:

1. An electronic component module comprising:
a substrate on which an electronic component is mounted;
at least one insulating member coupled to the substrate and having a surface on which a plating layer is formed; and
a molded portion covering the electronic component and the at least one insulating member,
wherein the insulating member is bonded to the substrate and a metal layer is formed on a bonding surface between the substrate and the insulating member.

2. The electronic component module of claim 1, wherein an upper surface of the insulating member is exposed to the outside of the molded portion, and a metal layer is formed on an upper surface of the insulating member.

3. The electronic component module of claim 2, wherein the metal layer is an under bump metallurgy layer.

4. The electronic component module of claim 2, wherein the plating layer is connected to the metal layer.

5. The electronic component module of claim 1, wherein an upper surface of the molded portion and an upper surface of the insulating member are disposed on the same plane.

6. The electronic component module of claim 1, wherein a plurality of insulating members are provided, and a distance between adjacent insulating members among the plurality of insulating members is less than a length of each of the insulating members.

7. The electronic component module of claim 1, wherein the molded portion is formed of one of a silicone gel, an epoxy molding compound (EMC), and polyimide.

8. The electronic component module of claim 1, wherein the insulating member is vertically coupled to the substrate.

9. An electronic component module, comprising:
a substrate on which an electronic component is mounted;
at least one conductive member vertically coupled to the substrate; and
a molded portion covering the electronic component and the at least one conductive member,
wherein an upper surface of the conductive member is exposed to the outside of the molded portion.

10. The electronic component module of claim 9, wherein the upper surface of the conductive member and an upper surface of the molded portion are disposed on the same plane.

11. The electronic component module of claim 9, wherein a plurality of conductive members are provided, and
a distance between adjacent conductive members among the plurality of conductive members is less than a length of each of the conductive members.

12. A method of manufacturing an electronic component module, the method comprising:
forming a metal layer on each of upper and lower surfaces of at least one insulating member;
providing a dummy member on which a photoresist layer is formed;
bonding the upper surface of the insulating member to a surface of the dummy member;
removing a remaining portion of the insulating member except a portion thereof corresponding to the metal layer;
forming a plating layer on a surface of the insulating member;
bonding a substrate, on which an electronic component is mounted, to the insulating member;
forming a molded portion to cover the electronic component and the insulating member; and
removing the dummy member.

13. The method of claim 12, wherein the removing of the dummy member includes removing both the photoresist layer and the dummy member such that the metal layer formed on the upper surface of the insulating member is exposed to the outside of the molded portion.
